(19) United States
(12) Patent Application Publication
(10) Pub. No.: US 2011/0226330 A1
(43) Pub. Date: Sep. 22, 2011

(54) AMORPHOUS SILICON SOLAR CELLS

(75) Inventors: Jeffrey C. Grossman, Brookline, MA (US); Alexander K. Zettl, Kensington, CA (US); Lucas Wagner, Somerville, MA (US)

(73) Assignee: THE REGENTS OF THE UNIVERSITY OF CALIFORNIA, Oakland, CA (US)

(21) Appl. No.: 13/058,992

(22) PCT Filed: Aug. 11, 2009
(86) PCT No.: PCT/US09/53351

§ 371 Date: Jun. 8, 2011

Related U.S. Application Data
(60) Provisional application No. 61/091,379, filed on Aug. 23, 2008.

(51) Int. Cl. H01L 31/0384; H01L 31/20; H01L 51/42; H01B 1/04; B82Y 99/00; B82Y 30/00; B82Y 40/00

(52) U.S. Cl. 136/258; 438/96; 252/501.1; 257/E31.048; 977/948; 977/700; 977/742; 977/840

(57) ABSTRACT

The present invention provides novel strategies for mitigating the Staebler-Wronski Effect (SWE), that is, the light induced degradation in performance of photoconductivity in amorphous silicon. Materials according to the present invention include alloys or composites of amorphous silicon which affect the elasticity of the materials, amorphous silicon that has been grown on a flexed substrate, compression sandwiched comprising amorphous silicon, and amorphous silicon containing nanoscale features that allow stress to be relieved. The composites are formed with nanoparticles such as nanocrystals and nanotubes. Preferred are boron nitride nanotubes (BNNT) including those that have been surface modified.

### CROSS-REFERENCE TO RELATED APPLICATIONS

The present application claims priority from U.S. Provisional Patent Application No. 61/091,379, filed on Aug. 23, 2008, which is hereby incorporated by reference in its entirety.

### STATEMENT OF GOVERNMENTAL SUPPORT

This invention was made with U.S. Government support under Contract Number DE-AC02-05CH11231 between the U.S. Department of Energy and The Regents of the University of California for the management and operation of the Lawrence Berkeley National Laboratory. This invention was also made with U.S. Government support under the auspices of the National Science Foundation by the University of California Berkeley under Grant No. 0425914. The U.S. Government has certain rights in this invention.

### REFERENCE TO SEQUENCE LISTING, COMPUTER PROGRAM, OR COMPACT DISK

None.

### BACKGROUND OF THE INVENTION

1. Technical Field

The present invention relates to the field of materials science, and in particular to amorphous silicon materials.

2. Background Art

Presented below is background information on certain aspects of the present invention as they may relate to technical features referred to in the detailed description, but not necessarily described in detail. The discussion below should not be construed as an admission as to the relevance of the information to the claimed invention or the prior art effect of the material described.

Hydrogenated amorphous silicon (a-Si:H) is used in many important devices currently on the market, from LCD flat panel televisions to large-area solar cells. It is possible to use this material to perform roll-to-roll deposition, which is one of the most promising paths towards mass production of solar cells. However, amorphous silicon degrades under exposure to light, an effect that so far cannot be practically mitigated and that has remained without microscopic explanation since its discovery in 1977 (Staebler-Wronski Effect, WSE). This effect has greatly limited the use of a-Si:H in a broad range of applications, particularly in solar cells, where it is responsible for a decrease in the energy conversion efficiency of 30%. For solar cells, crystalline silicon dominates the commercial and residential markets since it can provide the needed efficiency with the area constraints of a typical rooftop. Amorphous silicon on the other hand, could be more attractive due to its lower costs and thinner, lighter panels, but its efficiency after SWE degradation is too low, requiring a large area panel to power a home. Mitigating the SWE would boost the efficiency of a-Si:H solar cell enough to make them much more attractive as sources of residential and commercial power, but without a microscopic explanation of the effect, efforts at mitigation are mostly driven by trial and error.

### BRIEF SUMMARY OF THE INVENTION

### Technical Problem and Solution

The following brief summary is not intended to include all features and aspects of the present invention, nor does it imply that the invention must include all features and aspects discussed in this summary.

At present there is no known solution to mitigating the Staebler-Wronski Effect (SWE), that is, the light induced degradation in performance of photoconductivity in amorphous silicon. This is a problem which largely prevents the use of amorphous silicon as an active layer in photovoltaic devices. Traditionally, methods for moderately reducing the SWE have included alloying with other materials (e.g., selenium), or growing superlattice solar cells with crystalline silicon and amorphous silicon layers. While these approaches can mildly reduce the SWE, they are not ideal in that they fall far short of complete mitigation and are also costly to implement in traditional manufacturing processes, defeating one of the largest reasons for using a-Si:H as a photovoltaic material in the first place. Thus, the utility of such approaches in a-Si:H (amorphous silicon) photovoltaic cells is minimal. Accordingly, there is a need in the art for new approaches to mitigate the SWE effect in amorphous silicon.

High accuracy electronic structure calculations on amorphous silicon have now shed light on the microscopic mechanism responsible for the SWE. The results give rise to a microscopic model of the SWE that predicts a large majority of the experimental observations of the effect. This model, contrary to the mechanisms proposed for the past 30 years, does not require hydrogen diffusion or dangling bonds to explain the SWE. Instead, the major defects are regions of strained silicon-silicon bonds that are formed by simple, local bond switches. Such switches are able to create hole traps that are as strong or stronger than dangling bonds. In addition, these transformations are barrierless upon photo-excitation, a key ingredient needed to explain SWE. Further, this model is able to predict the way in which the SWE changes with respect to pressure and time, as well as the observation that the SWE still occurs at very low temperatures, which is difficult to explain using a standard diffusion-based model. As a result of this completely new understanding of the SWE, new mitigation strategies can be employed.

Accordingly, the present invention provides novel strategies for mitigating the SWE in amorphous silicon. In a first embodiment, materials are provided that affect the energetics of bond rotations. Specifically, these materials result in a more rigid network, such that bond rotations are suppressed. In one aspect of this embodiment, alloys are used to increase the rigidity of the bond network. The term “alloys” is intended to include composite materials where nanocrystals and nanoparticles such as fullerenes of various sizes are included in the a-Si. Thus, nanoparticles, e.g., nanotubes or nanospheres, or nanocrystals are embedded in the in the material to increase the rigidity of the bond network.

In a third embodiment, methods are used to reduce the internal stress in the a-Si:H (amorphous silicon). In one aspect of this embodiment, anisotropic pressure is used to control bond rotations and the resulting strained regions of bonds, thus improving the performance of the device. Pressure may be induced, for example, by flexing the substrate upon which the amorphous silicon is grown. Alternatively, pressure may be externally applied, such as in the form of a compression sandwich. In a similar vein, nanoscale features in the material may be used that allow stress to be relieved.

Thus there is provided a photovoltaic cell comprising a layer of hydrogenated amorphous silicon material applied to a substrate, wherein said hydrogenated amorphous silicon material contains within said layer a plurality of nanoparticles, forming a composite.

The composite may contain nanoparticles are nanocrystals, such as CoPt, Ag, Pd, Cu, CdSe/ZnS, CdS and CdSe. The composite may comprise, alternatively, or in addition, higher order structures, such as a fullerene (e.g., “Buckeyball”), nanotube (carbon or boron nitride) and nanorod. These alloying materials serve to reduce bond strain, as explained elsewhere herein. The analogy is given to placing plastic chips or strips in cement to prevent cracking. To this end, the nanoparticle may also be functionalized with an organic compound, such as a heteroaryl group, a polymer or an alkyl group. The term heteroaryl is used in its conventional sense, to mean groups having 5 to 16 ring atoms, preferably 5, 6, 9, or 10 ring atoms; having 6, 10, or 14 pi electrons shared in a cyclic array; and having, in addition to carbon atoms, from zero to three heteroatoms per ring selected from the group consisting of N, O, and S, provided there is at least one heteroatom. The term “alkyl” is also used in a conventional sense to mean a straight or branched chain of denotes a straight-chain or branched saturated hydrocarbon group having 1 to 20, preferably 1 to 10, more preferred 1 to 5 carbon atoms. The term polymer refers to a compound which is a series of repeating monomer units. An example is poly ethylene glycol.

The amorphous silicon may also be deposited on a flexible substrate, which is flexed before or after deposition of the layer so as to impart a strain on the layer. The layer may be mechanically compressed, anisotropically. The substrate may be provided with nanoscale topological features to which the a-Si:H adheres, to relieve stress in the bond network of said amorphous silicon. The topological features may be on the order of 1 to 20 nm and may be of a variety of shapes, such as holes, dimples, pillars, grooves or hills. Holes are illustrated. The topological features may be formed by depositing nanoscale particles on the substrate between the substrate and the amorphous silicon layer and the substrate such that the amorphous silicon layer contains an irregular under surface.

As for compression, a typical method of preparing transparent conductive films by the conventional coating process may be adapted according to the present teachings. Such a method involves the first step of applying a paint of conductive powder in a binder resin to a transfer plastic film and drying the coating to form a conductive layer, the second step of treating the conductive layer under a pressure (5 to 100 kg/cm 2) and heat (70 to 180° C.) for smoothing its surface, and the third step of stacking such conductive layers on a plastic film or sheet followed by thermo compression.

Thus, methods are provided for making a photovoltaic cell comprising a layer of hydrogenated amorphous silicon material applied to a substrate, wherein said hydrogenated amorphous silicon material is mixed with a plurality of nanoparticles, forming a composite. Also, a method or making a photovoltaic cell comprising applying a layer of hydrogenated amorphous silicon material applied to a substrate, further comprises depositing the hydrogenated amorphous silicon material on a patterned substrate having nanopores of between 10 and 500 nm in diameter, whereby the hydrogenated amorphous silicon material is deposited into the nanopores and is subjected to anisoptopic strain by depositing it into the nanopores.

### BRIEF DESCRIPTION OF THE DRAWINGS

FIG. 1 is a diagram showing one embodiment of the present invention, where a nanoscale structure is contained within the amorphous silicon. Shown are dangling bonds, and four-fold coordinated Si atoms.

FIG. 2 is a computer model showing a trap-free state, transition state, and a trap state. 202, 204 The model is based on the concept that Si under goes a bond switch process in both a ground and photo-excited state. The atoms indicated by arrows 202, 204 are switching their states.

FIG. 3 is a schematic drawing showing a textured substrate used to form an a-Si:H film on a template having nanometer size holes.

FIG. 4 is a schematic drawing of a structure used for incorporation into the a-Si:H film, wherein a nanotube is coated with an essentially spherical nanosized particle.

FIG. 5 is a schematic drawing of a structure used for incorporation into the a-Si:H film, wherein a nanotube is coated with an essentially cylindrical, nanosized particle.

FIG. 6 is a schematic drawing of a photovoltaic cell using the improved amorphous silicon film of the present invention.

### DISCLOSURE OF INVENTION AND MODE(S) FOR CARRYING OUT THE INVENTION

### Definitions

The term “hydrogenated amorphous silicon” is used in its conventional sense. That is, amorphous silicon refers to the non-crystalline allotropic form of silicon. Silicon is a four-fold coordinated atom that is normally tetrahedrally bonded to four neighboring silicon atoms. In crystalline silicon this tetrahedral structure is continued over a large range, forming a well-ordered lattice (crystal). In amorphous silicon this long range order is not present and the atoms form a continuous random network. Not all the atoms within amorphous silicon are four-fold coordinated. If desired, the material can be passivated by hydrogen, which bonds to the dangling bonds and can reduce the dangling bond density by several orders of magnitude. Hydrogenated amorphous silicon (a-Si:H) has a sufficiently low amount of defects to be used within devices. Hydrogenated amorphous silicon (a-Si:H) is widely applied commercially in thin film solar cells by means of plasma enhanced chemical vapor deposition (PECVD) techniques.

The term “amorphous silicon photovoltaic cell” includes an amorphous silicon cell, amorphous silicon-germanium alloy cell, amorphous silicon-carbon cell, and amorphous silicon-tin alloy cell. The present amorphous silicon solar cell typically comprises a first electrode, the first conductive film, a substantially intrinsic (i.e., undoped amorphous silicon) film, a second conductive film, and the second electrode on the substrate in this order. When it is desired to form either a p-n junction solar cell having p-n junctions with the necessary depletion layer, it is necessary to add dopant conduction modifying agents to move the Fermi level near the valence and conduction bands to form an effective solar cell p and n junctions. In such case, a relatively small amount (about 1% or less) of dopant is added to the amorphous silicon film layer, so that a sufficiently wide depletion region is maintained. The present methods may be employed so that the amorphous semiconductor film involved may be effectively doped to form such effective p and n junctions useful in photocells.

The term “nanotube” means an elongated structure having a diameter less than 1 micron. The structure may be either hollow or solid. Carbon nanotubes, for example, typically are hollow graphite tubules that typically have diameters ranging on the order of about 1 to 50 nm. Carbon nanotubes typically have rigid three-dimensional carbon structures that have high surface areas, low bulk density, and high crush strength. The present nanotubes may be multiwalled, single walled, and may be, e.g., carbon, boron nitride, or polymeric (See, Reiner et al., “Stable and robust polymer nanotubes stretched from polymersomes,” Proc. Nat. Acad. Sci. 103(5):1173-1177 (2006). Boron nitride nanotubes are discussed below.

The term “nanocrystal” is a nanostructure that is substantially monocrystalline. A nanocrystal as used here will have at least one region or characteristic dimension with a dimension of less than about 500 nm, e.g., less than about 200 nm, less than about 100 nm, less than about 50 nm, or even less than about 20 nm. Nanocrystals can be substantially homogeneous in material properties, or in certain embodiments can be heterogeneous (e.g., heterostructures). The term “nanocrystal” is intended to encompass substantially monocrystalline nanostructures comprising various defects, stacking faults, atomic substitutions, and the like, as well as substantially monocrystalline nanostructures without such defects, faults, or substitutions. In the case of nanocrystal heterostructures comprising a core and one or more shells, the core of the nanocrystal is typically substantially monocrystalline, but the shell(s) need not be. Representative nanocrystals include CoPt (, Ag, Pd, Cu, CdSe/ZnS (ZnS overcoated with Cd), CdS and CdSe. It is understood that the present nanocrystals are dispersed and may have surface modifications as is known in the art—see, e.g., U.S. Pat. No. 6,207,229 Bawendi, et al., issued Mar. 27, 2001, entitled “Highly luminescent color-selective materials and method of making thereof,” for a description of monodisperse nanoparticle selected from the group consisting of CdX, where x=S, Se, Te and an overcoating of ZnY, where Y=S, Se, uniformly deposited thereon.

The term “fullerene” means a compound including a three-dimensional carbon skeleton having a plurality of carbon atoms. The carbon skeleton of such fullerenes generally forms a closed shell, which may be, e.g., spherical or semi-spherical in shape. Alternatively, the carbon skeleton may form an incompletely closed shell, such as, e.g., a tubular shape. Carbon atoms of fullerenes are generally linked to three nearest neighbors in a tetrahedral network. Fullerenes may be designated as Cⱼ, where j is an integer related to the number of carbon atoms of the carbon skeleton. For example, C₆₀ defines a truncated icosahedron including 32 faces, of which 12 are pentagonal and 20 are hexagonal. Other suitable fullerenes include, e.g., C, where j may be at least 50 and may be less than about 250. Fullerenes are generally produced by the high temperature reaction of a carbon source, such as elemental carbon or carbon containing species. For example, sufficiently high temperatures may be created using laser vaporization, an electric arc, or a flame. Subjecting a carbon source to high temperatures forms a carbonaceous deposit from which various fullerenes are obtained. Typically, the fullerenes are obtained using a combination of solvent extraction and chromatography. Spherical fullerenes may be as small as C₂₀, and are also termed “Buckyballs.” Tubular fullerenes are the above described single wall and multiwall carbon nanotubes, having an extended graphene structure.

### Overview

Despite great promise as an inexpensive and efficient solar cell material[1], hydrogenated amorphous silicon (a-Si:H) is severely limited by the Staebler-Wronski effect (SWE)[2], in which the efficiency is degraded by 25-30% within a few hours of exposure to light. While there is a strong consensus[3] that unsaturated (dangling) silicon bonds play an important role in the SWE by acting as charge traps, it is also clear that they cannot explain the entire effect[4]. In fact, the photoconductivity can vary by more than a factor of ten at the same density of dangling bonds[5].

In experiments, it has been observed [6, 7, 8] that the quality of the random bond network of amorphous silicon is crucial to creating a high-quality sample. Large amounts of hydrogen are used, not to saturate dangling bonds, but to reduce the number of strained bonds. To date, however, it is unclear how this information about the deposition process relates to light-induced degradation, primarily because it is unfeasible to isolate individual defects in the amorphous material for study. Because of this, after 30 years of intense research aimed at understanding and mitigating this relatively straightforward macroscopic effect, a complete microscopic explanation for the performance degradation remains obscure.

As described in detail below, the amorphous hydrogenated silicon (a-Si:H) films prepared according to the present inventions have their most important utility in solar radiation energy-producing devices, and current control devices, but may be adapted for use as p-n junction devices including rectifiers, transistors or the like, where heretofore crystalline semiconductor bodies have been used.

The principles involved in the invention can be applied to various types of amorphous semiconductor films, both thick and thin films, which have recombination centers and other localized states inhibiting the control of the conductivity thereof, and are applicable to amorphous semiconductor films made of one or more elements, or combinations of elements which are mixtures or alloys of such elements. It is preferred that the a-Si:H be prepared as a thin film.

### Mechanism of Formation of Charge Carrier Traps

The first part of the present disclosure pertains to a discussion of the effect of the silicon bond network on the formation of charge carrier traps in amorphous silicon. Using a combination of classical force fields, density functional theory, and quantum Monte Carlo methods, we sampled the space of random networks through bond switches, in which two silicon atoms exchange neighbors. Our calculations demonstrate that bond switches can create dangling bonds and they also can create regions of strained bonds that trap holes. These defects are preferentially formed when a region contains both a hole and an excitation. Based on these results, a new picture of the SWE emerges that is able to accommodate the characteristic dependencies on temperature, pressure, and time observed in experiments.

We used a set of methods that increase in accuracy and computational expense. Filtering was done at each stage to ensure that the higher accuracy techniques were used only for potentially interesting samples of a-Si:H. First the Wooten-Winer-Weaire WWW [9] process using the Keating[10] potential was performed, which filters the large space of all bond networks to a set of amorphous low-energy networks. Each low-energy network was then perturbed by a single bond switch, and these new networks were again filtered based on their energy. These sets of bond networks were then passed to density functional theory (DFT) using the Siesta[11] program, where the geometries were optimized, which can potentially break bonds. The hole trap depth was then obtained by calculating the difference in ionization energies between the low-energy network and its perturbations, i.e.,

$$( {E}_{perturbed}^{+} - {E}_{perturbed}^{0} ) - ( {E}_{reference}^{+} - {E}_{reference}^{0} ) .$$

Networks with large trap depths were then singled out for analysis. We used the Vienna Ab-initio Simulation Package (VASP)[12] with the dimer method[13] and nudged elastic band method[14] to find the transition state between the two bond networks for the ground and positively charged states. Finally, diffusion Monte Carlo (DMC)[15] using the QWalk[16] quantum walk simulator program was used to evaluate the transition barrier in the ground, positively charged, excited neutral, and excited positively charged states. This approach was carried out for both 64-atom and 216-atom periodically repeated cells. The distributions are in agreement for both sizes. Because of the cost of finding many transition states and performing DMC calculations, we calculated only a few transition states in DFT on 216-atom cells, to confirm agreement with the 64-atom cells. The DMC results were all on 64-atom cells. All parameters were carefully checked for convergence[28].

The statistical nature of this search was particularly crucial: unlike a perfect crystal, in an amorphous material a single periodically repeated simulation cell is not necessarily representative of the entire phase space. Thus, we performed all possible bond switches for six independent a-Si:H samples containing 216 atoms and twenty samples containing 64 atoms. There were hundreds of possible switches in each sample, of which we kept those that increase the energy less than 1.3 eV in our model. The results, therefore, are statistical, deriving from the analysis of hundreds of computational samples; representative examples are shown here to simplify the discussion, but the trends discussed apply to the entire computational set.

After the classical model/DFT minimization procedure, we analyzed the electronic states to determine which network structures are hole traps/electron traps/low-energy absorbers. In our calculations, approximately 1-2 bond switches/nm³ change the electronic levels significantly from the reference structure, producing both electron and hole traps, as well as absorption at lower energy than the nominal 1.8 eV gap of amorphous silicon. We focused on the hole traps, since hole transport is the limiting factor in a-Si:H solar cells.

While the classical model used cannot break bonds, upon relaxation within DFT we found several instances where dangling bonds were formed, along with a complementary silicon atom with five bonds (a floating bond). A single bond switch was sufficient to form these dangling bond/floating bond pairs at either side of the switch, which results in a separation of approximately 1 nm, and only slightly higher energy (around 0.1 eV) than the original structure. This is similar in concept to the results of Biswas et al.[17] using a simpler tight-binding treatment of the electrons.

Surprisingly, however, we found that the deepest traps were not dangling bonds. To help understand why, we investigated two representative samples. The presence of the dangling bond allows nearby bonds to relax, since there are only three constraints on the 3-fold coordinated atom. A hole would then be forced to localize on the one atom, which is energetically less favorable due to an increase in the kinetic energy. The same reasoning holds true for a fully saturated but highly strained atom, as can be seen by the fact that the hole state does not localize on the highest strained atom. On the other hand, a group of two to four strained atoms allows the hole to be less confined, while still binding a valence electron much more weakly (and thus binding a hole more strongly) than unstrained atoms. The hole is localized, so this state is a hole trap. The region of strained bonds is a stronger trap because of quantum confinement of the hole.

These results establish that strained regions of silicon atoms could be as important as dangling bonds for hole transport in amorphous silicon and that these defects can be created by a single bond switch. We now turn to the mechanism by which these bond switches can occur, which requires detailed analysis of the reaction pathway. Reaction barriers are well-known to be poorly described by density functional theory; one must employ a more accurate first principles method for a reliable description[19]. Thus, we used DFT to obtain the reaction path on 64-atom samples using the dimer method[13], and then evaluated energy differences along the path using the highly accurate fixed node DMC method. The DMC barriers differed from DFT by up to 50%, which is enough to change the picture significantly, so the more accurate calculation was necessary in this case.

There are several potential light-induced events that may cause a bond switch. One is the collision and recombination of an electron and hole, which effectively locally heats the bond network, enabling the large ground-state barrier to be overcome. This mechanism is not supported by the high barrier and large energy cost in the ground state. Another possibility is through a light-induced electronic state other than the ground, neutral state. For this possibility, there are three major states: a hole, an electron, and an excited state, any two of which can potentially exist simultaneously in a region. Since holes are the slowest charge carriers, taking around 250 ns to exit a 500 nm device[20], they have the highest density of the three states. The second most numerous state is the excited state, which has a lifetime of around 10 ns[21]. Finally, the electron exits a 500 nm device in around 1 ns[20], so it is the most sparse. The following analysis does not depend strongly on the actual lifetimes; only on their ordering.

If a hole happens to be in the region and the product bond configuration is a hole trap compared to the initial configuration, the energy difference between configurations decreases by the difference in ionization energies, which can be around 0.1-0.7 eV according to our calculations. The presence of a hole therefore preferentially forms hole-attracting bond networks; however, the reaction barrier to forming such networks is still substantial. One can imagine two further modifications to the electronic state—first, the system could attract a second hole, which is not favored electrostatically and in our calculations does not decrease the barrier very much, or second, the system could absorb a photon, exciting the unpaired electron.

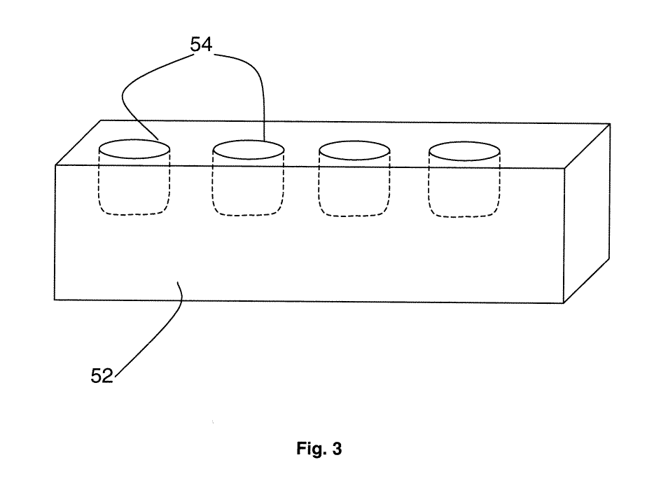

When the unpaired electron is photoexcited, a single bond can lose one electron from the hole and have the other excited to an anti-bonding state from the excitation, which allows a bond to break and switch. In the case presented here in FIG. 3, which is not unique in our samples, the energy ordering changes and the barrier is reduced to zero. Thus, when a hole is in a region that has the potential to change to a hole trap, and the region then absorbs a photon, a hole trap is formed with no barrier and a reduction in energy. When the excitation dissociates or decays, the energy ordering returns to the original condition and the barrier reappears.

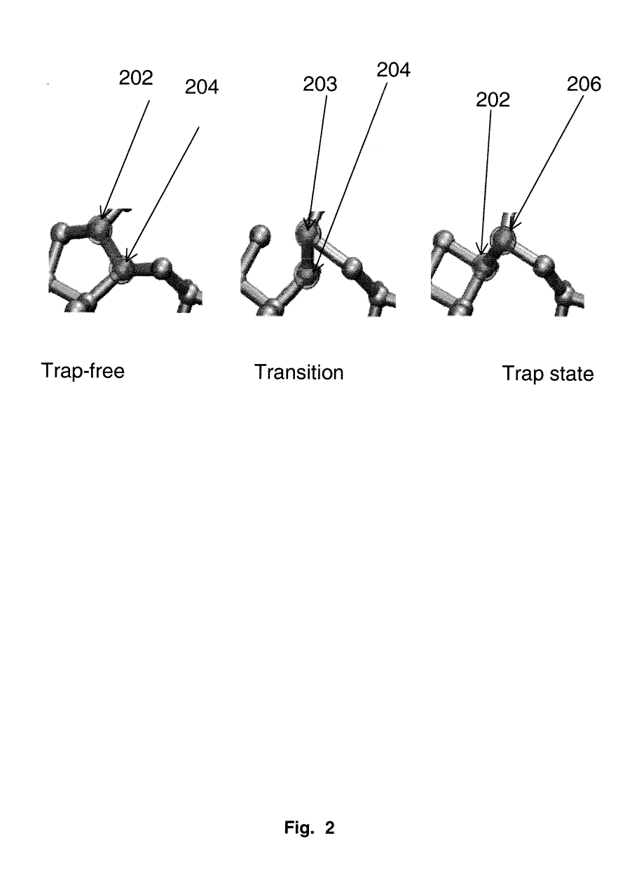

These calculations lead us to the following potentially important mechanism in the SWE. A hole travels through a-Si:H slowly. While it is in a region, bond network changes with hole traps become more energetically favorable, but there is still a large barrier for the bond switch necessary to change the bond network. If that region happens to absorb a photon, the barrier to switch bonds is zero or nearly so, and the network with a hole trap is lower in energy. The system then performs the bond switch, which leads to a hole trap state. Thus, a bond network of amorphous silicon with a delocalized mobile hole, when exposed to incident light, induces a bond switch, which creates a localized bound hole. FIG. 2 shows a lattice of silicon atoms in a trap free state (left) in a transition state (center) where one of the ordered silicon bonds between Si atoms 202 and 204 has moved to a nearby Si atom 203, and a trap state (right), where the bond is now between Si 202 and Si 206.

This explanation of the SWE has several implications about the macroscopic behavior of a-Si:H, which can be validated by comparing to experiment. We have shown that bond switches can form dangling bonds, so experiments that show that the number of dangling bonds increases with decreasing solar cell efficiency are consistent with our results. In our model, however, the dangling bonds are not the only hole traps. This is in agreement with the observation that the number of dangling bonds can vary by a factor of ten and still have the same efficiency in the same sample[5]. Furthermore, since strained silicon bonds are the major cause of decreased solar cell efficiency according to our model, our model predicts a reduction in the SWE under a decrease in hydrostatic pressure, since the bonds are then able to relax. Dangling bonds, on the other hand, are less affected by a change in pressure, since the lone electron is still present. This provides a way of gauging the relative importance of the two types of defects. In experiments on light soaking, a slight increase in the volume of the sample is observed[22], which according to our model would be due to an increase in strain. It has also been observed[23, 24] that if one removes the strain due to deposition, the SWE is reduced.

An advantage of taking a statistical approach is that we have the opportunity to compare the distribution of anneal barriers and trap depth. On 19 hole traps, the depth of the trap was anticorrelated with the anneal barrier, and the distribution of anneal barriers had a wide peak at around 0.70 eV. This anticorrelation is well-known in experiment; that is, traps formed at low temperatures are deeper, and a very similar distribution of anneal energies explains the temperature dependence of the SWE[25].

Based on our simulations, one can develop a simple rate model for the creation of traps. Our results show that the barrier to create a hole trap is zero when a hole and an excitation collide, so

$$\frac{d N}{d t} ∝ xp ,$$

where N is the density of defective regions, x is the concentration of excited states, and p is the concentration of holes. It is generally accepted that there is a concentration of holes proportional to

$$\frac{G}{N} ,$$

where G is the flux of photons. Furthermore, the probability that a photon will be absorbed by a region that is not defective is proportional to

$$\frac{G}{N} .$$

Therefore, the creation rate for a simultaneous hole/photon is

$$\frac{d N}{d t} ∝ \frac{G}{N} \cdot \frac{G}{N} ,$$

which has the solution N∝t^{1/3}G^{2/3} observed in experiment. Since the barrier is often nearly zero with a hole and excitation present, this analysis suggests that the defect creation rates in light would be nearly the same at all temperatures, which is the case in experiment[26], but difficult to explain using a model that depends solely on diffusion of defects.

### Designs For Improved Amorphous Silicon Solar Cells

The mechanism described above is now described below in terms of mitigation of the SWE. One approach is to redesign deposition processes to reduce the internal stress in the thin film, which reduces the number of hole traps. In the same vein, nanoscale features in the material that allow stress to be relieved could largely mitigate the SWE. An opposite strategy is to increase the rigidity of the bond network to prevent bond switches from happening in the first place; for example, by embedding nanocrystals in the material [27]. Finally, in our description of the SWE, the reaction is driven by an excitation combined with a hole that reverses the energy ordering of the defect-free and defective states. If a catalyst is introduced that reduces the ground state barrier, the defective bond network that is higher energy in the ground state can relax into the defect-free network at a lower than operating temperature, thus mitigating the SWE.

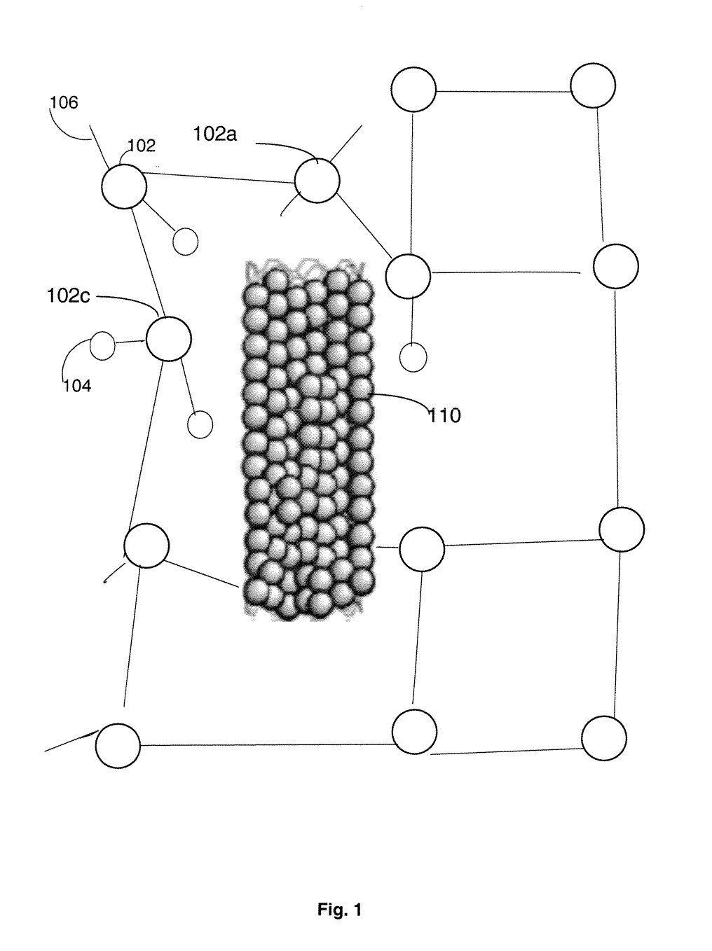

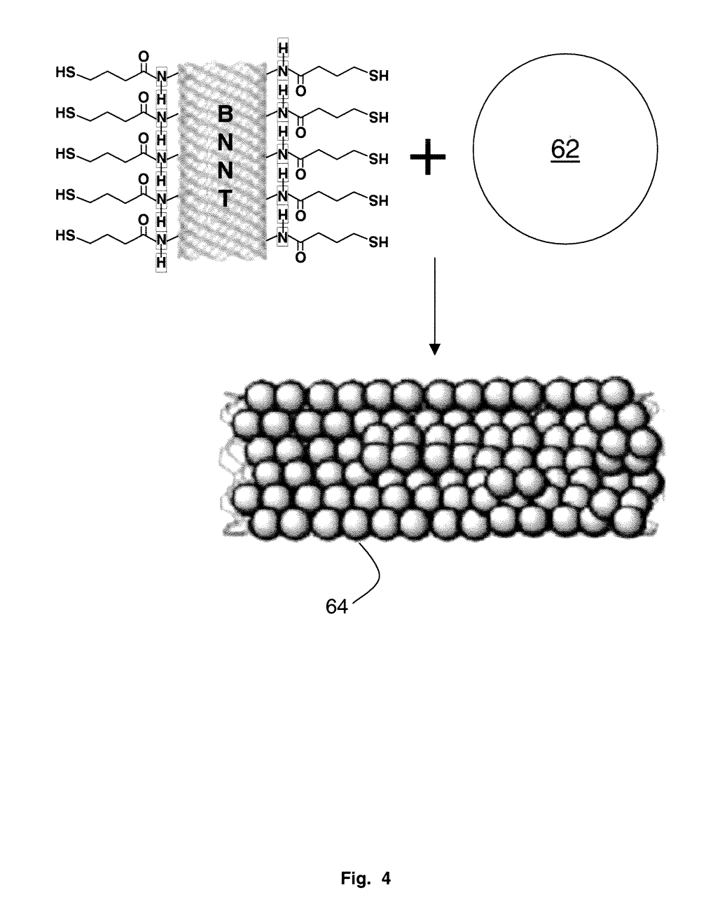

We have found that holes are trapped by both strained silicon bonds and dangling bonds and have provided a simple and plausible mechanism in which the traps can form. The depth of the hole traps is determined by a balance between quantum confinement of the hole and the amount of strain in the bond, for which accurate treatment of electrons is particularly crucial. Advances in this area have the opportunity of increasing the efficiency of amorphous silicon based solar cells by 30% or more, which is a significant step towards creating a less expensive alternative to higher efficiency crystalline silicon cells. FIG. 1 schematically illustrates an embodiment of the present invention where silicon atoms 102 have strain in bonds to silicon atoms 102a and 102c. In a region of disorder, dangling bonds 106 and hydrogen atoms 104 are also present. A nanostructure 110 is contained in the a-Si:H to reduce the amount of strain on the bond, and thus prevent hole trapping which reduces the photovoltaic property of the a-Si:H. The nanostructure 110 is described further in connection with FIG. 4.

As described above, the SW effect results less from dangling bonds but more from regions of strained bonds, which create a trap for a hole moving through the material. The presence of a dangling bond allows nearby bonds to relax, and a coordinated silicon atom affected by this attracts and localizes a hole. In consideration of this finding, described now below are designs of solar cells having improved performance due to minimizing regions of strained silicon bonds, and having lowered degradation of photovoltaic efficiency resulting from the SW effect.

1. An a-Si:H film deposited on a substrate and subjected to anisotropic stress. Subjecting the a-Si:H film to anisotropic stress mitigates the SW effect via a suppression of bond switch events and/or favoring bond switch events that help eliminate charge trap strain fields. This is accomplished by evaporating the a-Si:H film on a strained substrate (e.g., mechanically warped, piezo-distorted, or thermal-gradient strained). After film deposition, the strain is relieved in the substrate, but transferred to the film. A simple analogy is painting on an asymmetrically inflated rubber balloon, and then releasing some of the air. The paint is left with a built-in anisotropic strain field. In an alternative process, a non-flexible substrate is used, but subjected to pressure in an irregular pattern on the film, i.e., anisotropic strain is placed on the film so as to displace it slightly in portions of the film. A number of substrates can be used, including oxides, glass, quartz, semiconductors, epoxy board, composites, and polymers. Although the term anisotropic means literally not omni-directional, the present strain may be different in two or three dimensions and is contrasted with uniaxial or omniaxial strain. The film deposition may be carried out by chemical vapor deposition methods such as by plasma CVD, photo CVD or thermal CVD, or by physical deposition methods such as vacuum evaporation, sputtering, and ion plating.

Exemplary methods of deposition of a-Si:H on rigid substrates, which can be adapted for use for deposition onto the present flexible substrates, are described in U.S. Pat. No. 5,248,348 to Miyachi, et al, issued Sep. 28, 1993, entitled “Amorphous silicon solar cell and method for manufacturing the same.” The various layers needed for a complete solar cell are exemplified there. Also, as described there, the method employs a step of depositing a semiconductor film containing 20 atom % or less of bound hydrogen and/or deuterium to a thickness of 5 to 1000 Angstroms. A suitable method for deposition of hydrogenated amorphous silicon films is also given in U.S. Pat. No. 4,237,150 to Weismann, issued Dec. 2, 1980, entitled “Method of producing hydrogenated amorphous silicon film.” This method comprises decomposing a silane gas by directing a beam of silane gas, preferably in an ammonia atmosphere, at a tungsten or graphoil sheet heated to a temperature of about 1400°-1600° C., in a vacuum of about 10⁻⁶ to 10⁻⁴ ton, into a gaseous mixture of silicon and atomic hydrogen, and collecting the reaction products on a substrate mounted above the heated sheet. This process involves a single, possibly catalyzed interaction between a silane molecule and a hot tungsten or graphoil surface to produce atomic silicon and atomic hydrogen. Upon hitting the hot foil, a portion of the silane gas (SiH₄) dissociates into a mixture of Si, H, SiH, SiH₂ and SiH₃. The relative proportion of the products is a function of the foil temperature.

In another embodiment, one may modify, according to the present invention, certain methods described in U.S. Pat. No. 5,356,656 to Kuo, et al., issued Oct. 18, 1994, entitled “Method for manufacturing flexible amorphous silicon solar cell.” This method involves a method of manufacturing a flexible amorphous silicon solar cell includes the steps of: a) coating a PI (polyimide) varnish on a glass substrate; b) imidizing the PI varnish film; c) vacuum-depositing a metal film on the PI film; d) vacuum-depositing an amorphous silicon film on the metal film; e) vacuum-depositing a transparent conducting film on the amorphous silicon film; and f) separating the PI film from the glass substrate. In the method of this patent, the polymer film is applied to a rigid substrate. In the present method, the polymer film is itself the substrate, or is applied to a flexible substrate, such as a metal foil, which is in one configuration during deposition of the a-Si:H layer, then is moved into a different configuration, e.g., by changing the radius of curvature of the substrate. Other suitable flexible substrates include polyester, polyethylene terephthalate, epoxy resin, and acrylate resin.

2. An a-Si:H film deposited on topologically modulated substrates. If the a-Si:H film is deposited on topologically modulated substrates, a pathway will exist for the SW bond switching events to relieve charge trap strain fields. Examples include substrates with nanometer sized holes, dimples, pillars, grooves, and hills. The modulations can be either periodic in one or two dimensions (i.e., as in a diffraction grating or 2-D lattice), or entirely random (i.e., “rough surface”). Methods to produce the modulations include anodic aluminum growth (which can produce honeycomb arrays of holes), the use of zeolites (with pre-formed holes) or similar compounds, or the deposition of secondary materials onto the substrate prior to a-Si:H film deposition (i.e., deposition of fullerenes, carbon and non-carbon nanotubes, nanocrystals, nanorods, nanococoons, etc.).

FIG. 3 is a schematic drawing of a topologically modulated surface, showing a substrate 52 provided with a series of partial holes 54, with an exaggerated depth for purposes of illustration. A honeycomb surface is thus presented for deposition of the a-Si:H. Preferably the holes or indentations will have a depth less than their diameter, to facilitate an even thickness of film. There will be a number of closely spaced holes or ridges, which provide an undulating surface and resultant applied a-Si:H film, which extends into the holes or across the ridges.

One method involving the above mentioned anodic aluminum growth involves the use of etched GaN films using nanoporous anodic aluminum oxide (AAO) films as etch masks. AAO can be produced with ordered nanopores with a narrow, tunable diameter with distribution ranging from ˜10-500 nm.

3. Composite Films. If the a-Si:H film has internal structure that modifies the internal strain structure, the local charge trap configurations can be eliminated. (See FIG. 1.) The configuration is somewhat akin to adding plastic chips or fibers to concrete to prevent the concrete from cracking: the plastic fibers alter local strain fields. Here, nanoparticles with elastic moduli significantly different from those of a-Si:H are incorporated into the a-Si:H during the growth process. Examples of materials to incorporate include fullerenes, nanotubes, nanorods, nanocrystals, nanococoons, etc. Carbon nanotubes may be prepared by a number of methods, such as, for multiwalled nanotubes, M. Ishigami, J. Cumings, A. Zettl, S. Chen, and U. Dahmen. “A simple method for the continuous production of carbon nanotubes,” Chem. Phys. Lett., 319, 457 (2000). Single walled nanotubes may be prepared e.g., as described in Li et al., “Discrete dispersion of single-walled carbon nanotubes,” Chem. Commun., 3283-3285 (2005). The nanocrystals can be fabricated from essentially any convenient material or materials. In one aspect of the invention, one uses semiconductor nanocrystals include a wide range of different materials that exist as nanoparticles, e.g., having at least one cross sectional dimension of less than about 500 nm, and preferably, less than 100 nm. These nanocrystals may be comprised of a wide range of semiconductive materials, including for example, group III-V, group II-VI and group IV semiconductors or alloys of these materials. In particularly preferred aspects, CdSe, CdTe, InP, InAs, CdS, ZnS, ZnO, ZnSe, PbSe, PbS, ZnTe, HgTe, GaN, GaP, GaAs, GaSb, InSb, Si, Ge, AlAs, AlSb or PbTe semiconductors or their alloys are used as at least a portion of the nanocrystal component.

For details regarding nanococoons see, Cumings and Zettl, “Mass-production of boron nitride double-wall nanotubes and nanococoons,” Chemical Physics Letters, vol. 316, issue 3-4, pp. 211-216 (2000).

The nanostructures will preferably be prepared as individual particles for inclusion into the a-Si:H film. The particles may be pre-deposited on the substrate in dispersed form, or may be included in the materials being used to deposit the film. The particles will be added in a predetermined amount in order to provide strain control but not occupy excessive photovoltaic a-Si:H.

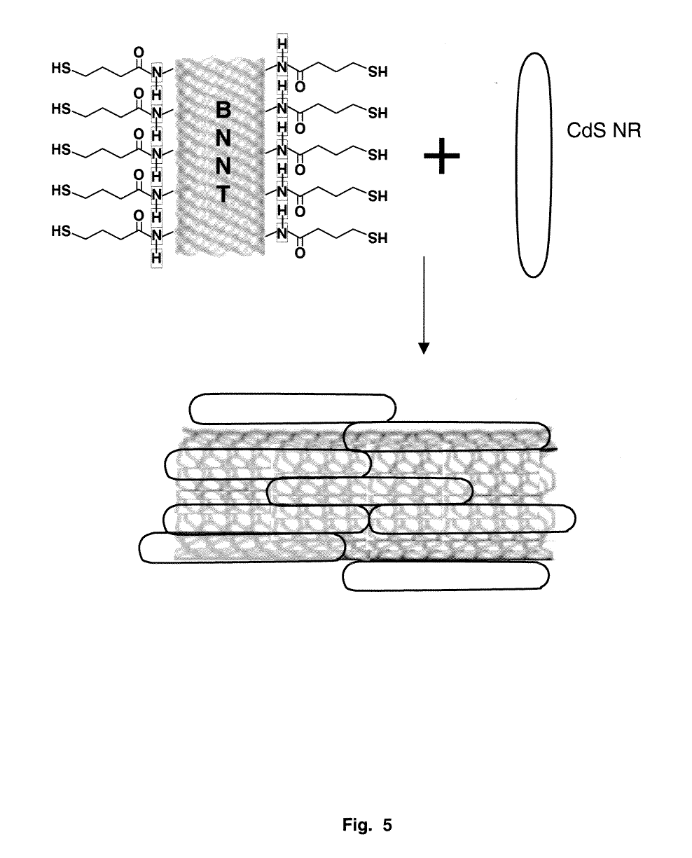

Of particular interest here are hybrid nanostructures, for example functionalized nanotubes or functionalized fullerenes. FIGS. 4 and 5 show examples of hybrid BN-based nanostructures that have been developed in the Zettl lab; see, for details, T. Sainsbury, T. Ikuno, D. Okawa, D. Pacil, J. M. J. Frechet, and A. Zettl. “Self-Assembly of Gold Nanoparticles at the Surface of Amine- and Thiol-Functionalized Born Nitride Nanotubes,” J. Phys. Chem. C 111, 12992-12999 (2007). These modified BNNTs may be incorporated into a-Si:H films as discussed. As described, BNNTs are first prepared according to any known procedure. See, e.g., Choehn and Zettl, U.S. Pat. No. 6,231,980, “BX CY NZ NANOTUBES AND NANOPARTICLES,” issued May 15, 2001. BNNTs are synthesized using a CVD method and subsequently exposed to an ammonia plasma in order to generate amine functional groups at the surface of the nanotubes. The amine functional groups are then used to couple a shortchain organic molecule terminated with a thiol, 3-mercaptopropionic acid (MPA), to the surface of the BNNTs via standard diimide-mediated amide formation, to yield the structure shown in FIG. 4, left side.

Referring now to FIG. 4, a boron nitride nanotube is shown which has been chemically modified to contain an exemplary functionality of HS—C—C—C(═O)—NH—, where the NH— binds to the BNNT and the sulfhydryl group provides a linker for various materials. Thus there is provided a sulfhydryl terminated alkyl group linked to the boron nitride nanotube. A particle 62 is adhered to the BNNT to form a heavily coated BNNT 64, where the particles substantially cover the lattice structure on the surface of the BNNT. The particles 62 are preferably small groups of individual atoms or molecules (commonly termed nanoparticles), and may be selected from a variety of different atoms, such gold silver, or palladium (preferably at lest partially coated with organic molecules or heterocyclic aromatic compound, see, e.g., Li et al., “Incorporation of Functionalized Palladium Nanoparticles within Ultrathin Nafion Films: A Nanostructured Composite for Electrolytic and Redox-Mediated Hydrogen Evolution,” Advance Functional Materials, Volume 18 Issue 11, Pages 1685-1693 (2008), describing positively charged Pd nanoparticles, stabilized with dimethylaminopyridine (DMAP). Gold nanoparticles may be attached to the terminal thol groups as described in the above referenced Sainsbury et al. paper. DMAP stabilized gold nanoparticles are added to freshly sonicated mercaptopropionic acid modified BNNTs. Other lower alkyl acids may be used, e.g., 1-10 carbon atoms. Other particles to be adhered to a nanotube include copper, which may also be coated with traditional organic or surfactant linkers during synthesis. For coating the present nanoparticles generally, see Swanson et al., “Improved Dual-Plasma Process for the Synthesis of Coated or Functionalized Metal Nanoparticles,” Plasma Science, IEEE Transactions on Volume 36, Issue 4, August 2008 Page(s):886-887. Further description of copper nanoparticles is contained in Tilaki et al., “Size, composition and optical properties of copper nanoparticles prepared by laser ablation in liquids,” Applied Physics A, Volume 88, Number 2, August 2007, pp. 415-419(5). As described there, colloidal copper nanoparticles were prepared by pulsed Nd:YAG laser ablation in water and acetone. The copper particles were rather spherical and their mean diameter in water was 30 nm, whereas in acetone much smaller particles were produced with an average diameter of 3 nm.

The particles may also be nanoparticles (small groups of atoms) of CdSe/ZnS, such as core-shell CdSe/ZnS quantum dots (QDots). See Cumberland et al., “Inorganic Clusters as Single-Source Precursors for Preparation of CdSe, ZnSe, and CdSe/ZnS Nanomaterials,” Chem. Mater., 2002, 14, 1576-1584 for a preparation method. Also, CdS and CdSe nanoparticles or nanocrystals are useful in the present method. CdS and CdSe nanoparticles may be synthesized in poly(2-(dimethylamino) ethyl methacrylate-co-acrylic acid (pDMAEMA-AA) co-polymer.

Other linking groups, such as —NH2, may be attached to a nanotube. See, e.g., Ikuno et al., “Amine-functionalized boron nitride nanotubes,” Solid State Communications, 142 (2007)643-646. In this paper, having a present inventor as a co-author, amine functional were generated at the surface of the BNNTs using an aggressive non-equilibrium ammonia glow plasma treatment. BNNTs were synthesized on Si substrates by thermal decomposition of B and MgO powders in an ammonia environment at 1200° C. in an electric furnace. Average diameters and lengths of the tubes were 20 nm and over 10 μm, respectively. Amine functional groups were introduced at the surface of the BNNTs using an ammonia plasma treatment in a microwave plasma generator.

Also, as shown in FIG. 5, Cd (cadmium sulfide) nanorods may also be used to be linked to a functionalized BNNT surface, and substantially coat the surface of the BNNT. The rods are shown as axially aligned with the nanotube. See Chen et al., “One-Step Fabrication of CdS Nanorod Arrays via Solution Chemistry,” ASAP J. Phys. Chem. C, ASAP Article, Aug. 9, 2008, for exemplary synthetic methods. As discussed elsewhere, other nanotubes may be used in the preparation of the complexes of FIGS. 4 and 5.

It should be noted that nanocrystals and nanorods with surfactant-like coatings, used both individually and in combination, are of particular interest, as they provide sharp elastic modulus contrast and can thereby alter local strain fields within the a-Si:H. Different methods have been recently reported in the literature for synthesizing these BN nanostructure crystalline materials. These include techniques such as: plasma arc discharge, laser ablation and catalytic decomposition. Also, BN nanotubes have been obtained from a substitution reaction of carbon nanotubes at 1773 K. Further production methods are described in Ayala-Sistos et al, “BN Nanorod Production Using Mechanical Alloying,” AZojomo (ISSN 1833-122X) Volume 2 Jan. 2006. As disclosed there, covered nanotubes and nanorods were obtained using mechanical alloying techniques. Different steel and tungsten carbide balls and containers were used in the experimental procedure. Also, two different elements (iron and silicon) were added to the initial boron-nitrogen mixture.

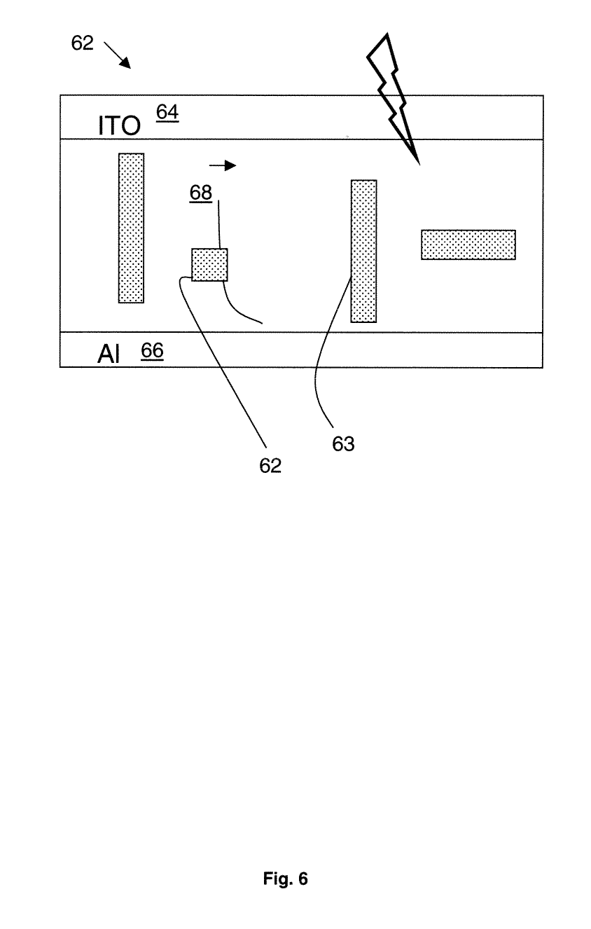

FIG. 6 shows an exemplary solar cell prepared according to the present invention where the amorphous silicon is prepared as a composite, as described above. The cell is a solar cell 62 where light enters through an ITO transparent layer 64 to strike a-Si:H layer 68. This layer has been modified with nanoparticles 62, 63 to form a composite. In this illustration, nanoparticle 62 represents e.g., a CdSe particle. In addition, a nanoparticle in the form of a surfactant modified boron nitride nanotube (BNNT) 63 is also contained in the composite. There is a large number of each type of nanoparticle, and the particles may comprise a range of concentrations, with higher concentrations reducing the photovoltaic effect by displacing the a-Si:H material. Between about 1 and 35% nanoparticles, or 10-33% are contemplated. The nanoparticles are much smaller than the thickness of the film, and are enlarged for purposes of illustration. The a-Si:H layer 68, as is known, is a thin film subdivided into p-i-n regions by doping. A bottom electrode 66, preferably of aluminum collects current. A grid electrode on the upper surface and various protective films are also used, again, as is known in the art.

### CONCLUSION

The above specific description is meant to exemplify and illustrate the invention and should not be seen as limiting the scope of the invention, which is defined by the literal and equivalent scope of the appended claims. Any patents or publications mentioned in this specification are indicative of levels of those skilled in the art to which the patent or publication pertains as of its date and are intended to convey details of the invention which may not be explicitly set out but which would be understood by workers in the field. Such patents or publications are hereby incorporated by reference to the same extent as if each was specifically and individually incorporated by reference, such incorporation being for the purpose of further describing and enabling the method or material referred to.

### REFERENCES

1. A. Shah, P. Torres, R. Tscharner, N. Wyrsch, and H. Keppner, Science 285, 692 (1999).
2. D. Staebler and C. Wronski, Appl. Phys. Lett. 31, 292 (1977).
3. M. Stutzmann, W. Jackson, and C. Tsai, Phys. Rev. B 32, 23 (1985).
4. H. Fritzche, Annu. Rev. Mater. Res. 31, 47 (2001).
5. T. Shimizu, Jpn. J. of Appl. Phys. 43, 3257 (2004).
6. J. Boland and G. Parsons, Science 256, 1304 (1992).
7. G. Cody, T Tiedje, B. Abeles, B. Brooks, and Y. Goldstein, Phys. Rev. Lett. 47, 1480 (1981).
8. S. Sriraman, S. Agarwal, E. S. Aydil, and D. Maroudas, Nature 418, 62 (2002).
9. F. Wooten, K. Winer, and D. Weaire, Phys. Rev. Lett. 54, 1392 (1985).
10. P. N. Keating, Phys. Rev. 145, 637 (1966).
11. J. M. Soler, E. Artacho, J. D. Gale, A. García, J. Junquera, P. Ordejánchez-Portal, J. Phys. Cond. Matter 14, 2745 (2002), URL stacks.iop.org/0953-8984/14/2745.
12. G. Kresse and J. Furthmüller, Phys. Rev. B 54, 11169 (1996).
13. G. Henkelman and H. Jonsson, J. Chem. Phys. 111, 7010 (1999).
14. G. Henkelman, B. P. Uberuaga, and H. Jónsson, The Journal of Chemical Physics 113, 9901 (2000), URL link.aip.org/link/?JCP/113/9901/1.
15. W. M. C. Foulkes, L. Mitas, R. J. Needs, and G. Rajagopal, Rev. Mod. Phys. 73, 33 (2001).
16. L. Wagner, M. Bajdich, and L. Mitas, arXiv p. 0710.4361 (2007).
17. R. Biswas, B. Pan, and Y. Ye, Phys. Rev. Lett. 88, 205502 (2002).
18. J. Tersoff, Phys. Rev. B 38, 9902 (1988).
19. J. C. Grossman and L. Mitas, Phys. Rev. Lett. 79, 4353 (1997).
20. A. Luque and S. Hegedus, Handbook of Photovoltaic Science and Engineering (John Wiley and Sons, 2003), pp. 505-565.
21. Y. Kanemitsu, S, Nihonyanagi, Y. Fukunishi, and T. Kushida, Phys. Stat. Sol. (a) 190, 769 (2002).
22. T. Sakamoto, N. Yoshida, T. Kishida, S, Nonomura, T. Gotoh, M. Kondo, A. Matsuda, T. Itoh, and S, Nitta, J. Non-Cryst. Solids 266-269, 481 (2000).
23. R. B. Wehrspohn, S. C. Deane, I. D. French, I. Gale, J. Hewett, M. J. Powell, and J. Robertson, J. of Appl. Phys. 87, 144 (2000), URL http://link.aip.org/link/?JAP/87/144/1.
24. R. S. Crandall, Phys. Rev. B 43, 4057 (1991).
25. Q. Zhang, H. Takashima, J.-H. Zhou, M. Kumeda, and T. Shimizu, Phys. Rev. B 50, 1551 (1994).
26. P. Stradins and H. Fritzsche, J. Non-Cryst. Solids 198200, 432 (1996).
27. S. Zhang, X. Liao, L. Raniero, E. Fortunato, Y. Xu, G. Kong, H. Aguas, I. Ferreira, and R. Martins, Solar Energy Materials & Solar Cells 90, 3001 (2006).
28. Energies were calculated within SIESTA (Spanish Initiative for Electronic Simulations with Thousands of Atoms) with a DZP (double-zeta plus polarization) basis, 300 meV energy shift, and PBE (Perdew-Burke-Ernzerhof) functional. VASP calculations used a 245 eV energy cutoff, ultrasoft potentials, and PW-91 (Perdew-Wang exchange and correlation) functional. DMC calculations used a Slater-Jastrow trial function with the one-particle orbitals from SIESTA with a TZTP (triple zeta-triple polarized) basis, variance-minimized Jastrow coefficients, and a timestep of 0.05 Hartrees⁻¹

1. A photovoltaic cell comprising a layer of hydrogenated amorphous silicon material applied to a substrate, wherein said hydrogenated amorphous silicon material contains within said layer a plurality of nanoparticles, forming a composite.

2. The composite of claim 1 where the nanoparticles are nanocrystals.

3. The composite of claim 2 where the nanocrystals are semiconducting nanocrystals.

4. The composite of claim 2 where the nanocrystals are selected from the group consisting of CoPt, Ag, Pd, Cu, CdSe/ZnS, CdS, and CdSe.

5. The composite of claim 1 where the nanoparticles are selected from the group consisting of fullerene, nanotube, and nanorod.

6. The composite of claim 5 where the nanoparticles are in the form of a boron nitride nanotube.

7. The composite of claim 1 where the nanoparticles have been functionalized with an organic compound selected from the group consisting of a heteroaryl group, a polymer and an alkyl group.

8. The photovoltaic cell of claim 1, wherein said amorphous silicon is a layer on a flexible substrate, which is flexed before or after deposition of the layer so as to impart a strain on the layer.

9. The photovoltaic cell of claim 1, wherein said amorphous silicon is compressed anisotropically.

10. The photovoltaic cell of claim 1, wherein said amorphous silicon contains nanoscale topological features to relieve stress in the bond network of said amorphous silicon.

11. The photovoltaic cell of claim 10 wherein the topological features are on the order of 1 to 20 nm and are holes, dimples, pillars, grooves or hills.

12. The photovoltaic cell of claim 10 where the topological features are formed by depositing nanoscale particles on the substrate between the substrate and the amorphous silicon layer and the substrate such that the amorphous silicon layer contains an irregular under surface.

13. A photovoltaic cell comprising a layer of hydrogenated amorphous silicon material applied to a substrate, the substrate comprising a patterned substrate having nanopores of between 1 and 20 nm in diameter, whereby the hydrogenated amorphous silicon material is in the nanopores and subjected to anisoptopic strain by depositing it into the nanopores.

14. A method of making a photovoltaic cell comprising a layer of hydrogenated amorphous silicon material applied to a substrate, wherein said hydrogenated amorphous silicon material is mixed with a plurality of nanoparticles, forming a composite.

15. The composite of claim 2 where the nanoparticles have been functionalized with an organic compound selected from the group consisting of a heteroaryl group, a polymer and an alkyl group.

16. The composite of claim 3 where the nanoparticles have been functionalized with an organic compound selected from the group consisting of a heteroaryl group, a polymer and an alkyl group.

17. The composite of claim 4 where the nanoparticles have been functionalized with an organic compound selected from the group consisting of a heteroaryl group, a polymer and an alkyl group.

18. The composite of claim 5 where the nanoparticles have been functionalized with an organic compound selected from the group consisting of a heteroaryl group, a polymer and an alkyl group.

19. The composite of claim 18 where the organic compound is an alkyl group linked to a nanoparticle which is a nanotube of either boron nitride or carbon.
